(19) United States
(12) Patent Application Publication
(10) Pub. No.: US 2011/0037053 A1
(43) Pub. Date: Feb. 17, 2011

(54) HIGH QUANTUM EFFICIENCY LIGHTING DEVICE WITH LIGHT INFLUENCING ELEMENT

(75) Inventors: Rifat Ata Mustafa Hikmet, Eindhoven (NL); Ties Van Bommel, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/936,546

(22) PCT Filed: Apr. 10, 2009
(86) PCT No.: PCT/IB09/51524

§ 371 Date: Oct. 6, 2010

(30) Foreign Application Priority Data
Apr. 17, 2008 (EP) 08154737.4

(51) Int. Cl. H01L 33/06

(52) U.S. Cl. 257/13; 257/E33.005

(57) ABSTRACT

The present invention relates to a high quantum efficiency lighting device comprising a solid state light source (54) and at least one light influencing element (10), being adapted to influence light emitted from solid state light source. The light influencing element (10) comprises a first electrode layer (11), and a second electrode layer (13), wherein the second electrode layer (13) is biased to remain in a rolled-up state, and adapted to be unrolled into an unrolled state in response to an electric potential applied between the first and second electrode layers, said second electrode layer in its unrolled state, extending across said optical light path, and being adapted to influence light emitted from the solid state light source (54).

### TECHNICAL FIELD

The present invention relates to a high quantum efficiency lighting device comprising a solid state light source and at least one light influencing element, being adapted to influence light emitted from solid state light source.

### BACKGROUND OF THE INVENTION

A high quantum efficiency lighting device is herein defined as a device with the ability to control the direction, shape, color or collimation of a beam of light emitted by such a high quantum efficiency lighting device, which is desirable in many applications ranging from general lighting to special lighting applications with less than 70% reduction in the intensity of the light generated by the light source. Since solid state light sources (inorganic light emitting diodes (LEDs), organic light emitting diodes (OLEDs) and lasers) are considered to become the next generation of lighting sources it is of great interest to influence beams of light from a solid state light source, e.g. by converting light emitted from the solid state light source.

One way to influence light is to convert it to another color, which generally has been performed through placing phosphors over at least some of the solid state light sources in a solid state light source device, converting light emitted by the solid state light sources to one or more different colors. Hence, the light is influenced in a certain manner, and there is no way to actively control how and when to influence the light.

### SUMMARY OF THE INVENTION

In view of the above mentioned needs, a general object of the present invention is to provide a high quantum efficiency lighting device for controlling the direction, shape, color or collimation of a solid state light source by means of a light influencing element.

According to the present invention, these and other objects are achieved through a high quantum efficiency lighting device which comprises a solid state light source, and at least one light influencing element that is arranged in an optical path of the light emitted from the solid state light source. The light influencing element further comprises a first electrode layer, and a second electrode layer. The second electrode layer is biased to remain in a rolled-up state, and adapted to be unrolled into an unrolled state in response to an electric potential applied between the first and second electrode layers. When the second electrode layer is in its unrolled state, it extends across the optical light path, and is adapted to influence light emitted from the solid state light source.

The influence of the light influencing element may be for example conversion to another color or beam shaping.

The quantum efficiency of a lighting device is here defined as the quantum output (number of photons) from the device in relation to the quantum output of the light source. In other words, it is an indication of the efficiency of the light influence of the light influencing element. It should be noted that the energy of each photon may be reduced by the influencing, leading to a significantly lower energy efficiency (energy losses).

By a high quantum efficiency lighting device is thus intended a device wherein a large portion of the photons generated by the light source are emitted by the device. This is important for any lighting device intended to be used for illumination of surrounding objects. Generally, such a device is capable of providing indirect lighting, i.e. a user does not look straight into the lighting device, but looks at objects illuminated by the device.

Preferably, the quantum efficiency of the light influencing element is at least 40%, preferably more than 60%, and most preferably 80%. It should be noted that this quantum efficiency includes an intrinsic quantum efficiency, e.g. related to the phosphor material of a color converting light influencing element, as well as a system quantum efficiency, caused e.g. by reflection and isotropic light distribution in general.

As an example, for a phosphor based color converting element, the quantum efficiency of this conversion process is preferably at least 40%, meaning that at least 40% of the photons generated by the solid state light source leaves the lighting device after the color is altered. This can be compared with the quantum efficiency of a color display device such a liquid crystal display (LCD), which has a low efficiency typically less than 5% of the light generated by the light source leaves the display.

A roll shaped electrode is known per se, and is described in for example U.S. Pat. No. 5,519,565. However, such roll shaped electrodes have been used as blinds, light absorbing filters, and light modulators in e.g. displays. In display applications they work as shutters whereby light is either absorbed or reflected away from the viewing field of the observer. In other words, light is lost when the device is activated. In color displays the colors are produced by absorbing parts of white light by absorbing filters, and since displays cause loss of light in the activated state they are not suitable for use in lighting applications.

Furthermore, conventional light sources such as an incandescent lamp, e.g. a light bulb, may heat its filament to a few thousands of Celsius. A roll-shaped electrode as disclosed in U.S. Pat. No. 5,519,565 would not bear to be subjected to these temperatures even when places further away from the light source where the temperature is very high.

The present invention is based on the realization that a solid state light source has a relatively low heat generation. For example, a surface of an inorganic LED may reach 50-200 Celsius at its emitting side, depending on the application. As such being the case, the inorganic LED does not produce more heat than what the light influencing element can bear. Additionally, an inorganic LED is typically provided with means for leading the heat from the light emitting side of the inorganic LED, e.g. a heat sink that dissipates the heat through dissipating fins, so that the heat does not accumulate around the entire inorganic LED device. Concerning OLEDs, the surface temperature is even lower.

The second electrode layer may comprise a dielectric layer, which may contribute to the second electrode layer's elastic characteristics. Such characteristics may be created through shrinkage of the dielectric layer during manufacturing. The dielectric layer may also be a substrate acting as a support for the second electrode layer, which may be for example an aluminium foil or an ITO.

The dielectric layer can further be phosphor adapted to influence light emitted from the solid state light source. For example, the light influencing element may produce white light by using one or more various luminescent phosphor materials comprised in e.g. the second electrode layer to, in its unrolled state, convert the emitted blue light from the solid state light source into light of a longer wavelength.

Moreover, the second electrode layer may be adapted to act as a reflector in its unrolled state, and hence collimate light emitted from the solid state light source. The direction of light may hence be altered, having one direction when the second electrode layer is rolled-up and another when the second electrode layer is unrolled.

The second electrode layer may comprise at least two separately rollable portions arranged to extend across the same part of the path of light emitted from the solid state light source. In this way several different effects can be generated on this part of the path of light. The portions of the second electrode layers may be alternately controlled by applying a voltage difference between the first electrode and one of the portions of the second electrodes at a time, hence alternately covering the same part of the path of light emitted from the solid state light source.

Alternatively, or in combination, the second electrode layer may comprise at least two separately rollable portions arranged to extend across different parts of the path of light emitted from the solid state light source.

In this way a number of rollable portions can produce the same number of different effects on different parts of the light emitted from the solid state light source. The portions of the second electrode layers may be simultaneously or alternately controlled by applying a voltage difference to the portions to be unrolled. For example, two portions of the second electrode layer may be controlled to unroll at the same time covering different halves of the path of light. One half of the light may hence be influenced in one way while the other half may be influenced in another way, e.g. by being converted to different colors.

The high quantum efficiency lighting device may comprise at least two light influencing elements in a stacked structure. The second electrode layer of each light influencing element may be simultaneously or alternately controlled. Several of the second electrode layers are unrolled by applying a voltage between the first electrode layer and the second electrode layers that are to roll out. For example a number of light influencing elements may be unrolled at the same time to produce a combined effect on the same part of the light emitted from the solid state light source.

The light influencing element may be arranged in optical contact with the solid state light source, e.g. by means of an optical contact layer.

The light influencing element may further comprise reflector means to collimate the light emitted from the solid state light source.

If there are no reflector means surrounding the device the light influencing element may act as a side-top emitter, the second electrode layer being the side emitter, which directs the majority of the light from the solid state light source out the side.

In another embodiment of the present invention the high quantum efficiency lighting device may comprise a first collimator arranged between the solid state light source and the light influencing element. The solid state light source may be arranged in the bottom of the first collimator, and the light influencing element may be arranged to cover an exit opening of the first collimator. The light influencing element adjusts shape, direction and collimation of a beam of light emitted from the solid state light source, when the second electrode is in its unrolled state.

In addition the high quantum efficiency lighting device may comprise a second collimator, arranged to collimate light that have passed through the second electrode layer being in its unrolled state. When the second electrode layer of the light influencing element is in its rolled-up state the light will be influenced by the first collimator. However, when the second electrode layer is in its unrolled state it may influence the light and direct it to the second collimator for shaping the beam. The light will in other words be influenced by both collimators when the second electrode layer is in its unrolled state.

Furthermore, the high quantum efficiency lighting device may comprise a plurality of tapered light influencing elements arranged to form an inner funnel-shaped reflector when the second electrode layers are in the unrolled state. The funnel-shaped reflector is arranged with the narrow opening of the funnel on the emitting side of the solid state light source. In this manner the light influencing elements are together acting as a regular reflector, although with the ability to be inactivated, which is the case when the second electrode layers are in the rolled-up state.

In addition the high quantum efficiency lighting device may comprise an outer reflector, adapted to reflect the light when the plurality of second electrode layers of the light influencing elements are in their rolled-up state. When the second electrode layers of the light influencing elements are rolled-up the light is reflected by the outer static collimator and when the second electrode layers of the light influencing elements are unrolled the light is reflected by the inner collimator which they form.

### BRIEF DESCRIPTION OF THE DRAWINGS

In the following, embodiments of the present invention will be described in detail, with reference to the accompanying, exemplifying drawings on which:

FIG. 1a-b are perspective views of a light influencing element.

FIG. 2a-c show various exemplary light influencing element configurations.

FIG. 3a-b show various exemplary light influencing element configurations.

FIG. 4a-c show various exemplary stacked light influencing element configurations.

FIG. 5 is a cross-section high quantum efficiency lighting device, where the light influencing element is mounted on a LED chip.

FIG. 6 is a cross-section view of a high quantum efficiency lighting device, where the light influencing element is used as in a remote phosphor configuration.

FIG. 7a-b is a cross-section view of a high quantum efficiency lighting device, where the light influencing element, mounted on a collimator, is arranged for beam shaping.

FIG. 8a-b is a cross-section view of a high quantum efficiency lighting device, where a second collimator is arranged to collimate light that has passed through and been converted by the light influencing element.

FIG. 9 is a cross-section view of a high quantum efficiency lighting device where the light influencing element is arranged to alter the direction of a beam of light.

FIG. 10 is a perspective view of a high quantum efficiency lighting device where a plurality of light influencing elements are arranged to form an inner collimator.

### DETAILED DESCRIPTION OF PREFERRED EMBODIMENTS

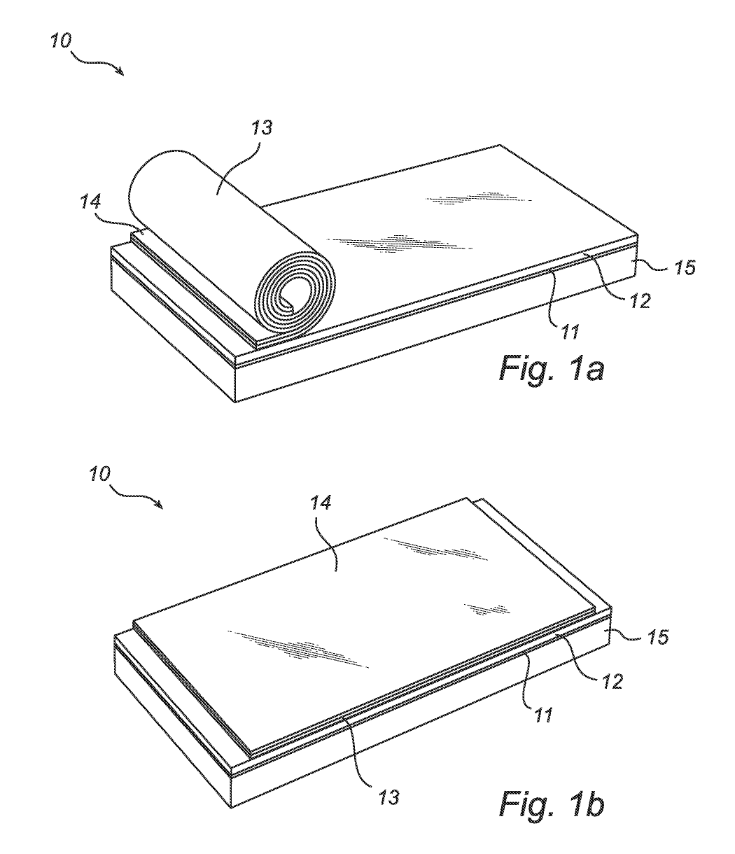

The invention will be described with reference to the light influencing element 10 in FIG. 1. The light influencing element 10 comprises a first electrode layer 11, here arranged on a substrate 15, a dielectric layer 12, and a second electrode layer 13 in form of a rollable electrode. In FIG. 1, the second electrode layer comprises a dielectric material 14.

In FIG. 1a the second electrode layer 13 is in its rolled-up state, where no voltage is applied between the two electrode layers, 11, 13, and in FIG. 1b it is in its unrolled state, a sufficient voltage being applied between the electrode layers, 11, 13. The second electrode layer 13 in the present invention is adapted to influence light emitted by a LED (not shown in FIG. 1), e.g. by converting it to another color, reflecting it, or shaping the beams of light, when it is in its unrolled state. The unrolled second electrode layer 13 extends over the path of light from the LED that it covers, and will produce an effect on that part of the path of light. The path of light may be the full path of light emitted from a LED, or only a part of it.

It may be assumed that three (or four) forces determine the behavior of the rollable second electrode layer 13, which forces are the elastic force, and the electrostatic force, but also the “van der Waals” force and to a minor extend the gravitational force. The elastic force may be a result of e.g. shrinkage during manufacturing. By applying a voltage between the first 11 and second electrode 13, an electrostatic force directed to unroll the second electrode layer 13 and keep it in the unrolled state, is obtained. The elastic force acts on the second electrode layer 13 even when there is no electric field present, and is directed at rolling it up. The electrostatic force is the attractive force between the first and second electrode layer 11, 13 by applying a voltage. The “van der Waals” force is the force between the dielectric material 14 and the dielectric material 12. This force depends on the distance between the two media, the roughness of the media and the material properties; the smaller distance the larger “van der Waals” force. The gravitational force acts upon the second electrode layer 13 which also depends on the orientation of it. It is very thin and has therefore a very low mass, and accordingly the gravitational force is probably negligible.

To unroll the second electrode layer 13, and for the second electrode layer 13 to stay in its unrolled state the elastic force always acting on the second electrode layer 13, directed at rolling it up, must be overcome. For this purpose, a sufficient electrostatic force, obtained by applying an adequate voltage between the first 11 and second 13 electrode layers, must be generated. In order to return the electrode layer 13 to its rolled up state the voltage is switched of, resulting in that no electrostatic force acts on the rollable second electrode layer 13. The elastic force causes the second electrode layer to roll up under the condition that this force is greater than the “van der Waals” force.

The electrode layers may be transparent such as indium tin oxide, ITO, electrodes for reducing transmission losses. The second electrode may further comprise linear indentations in order to remove parts of the second electrode layer if it is relatively thick and hence require a higher voltage to be unrolled.

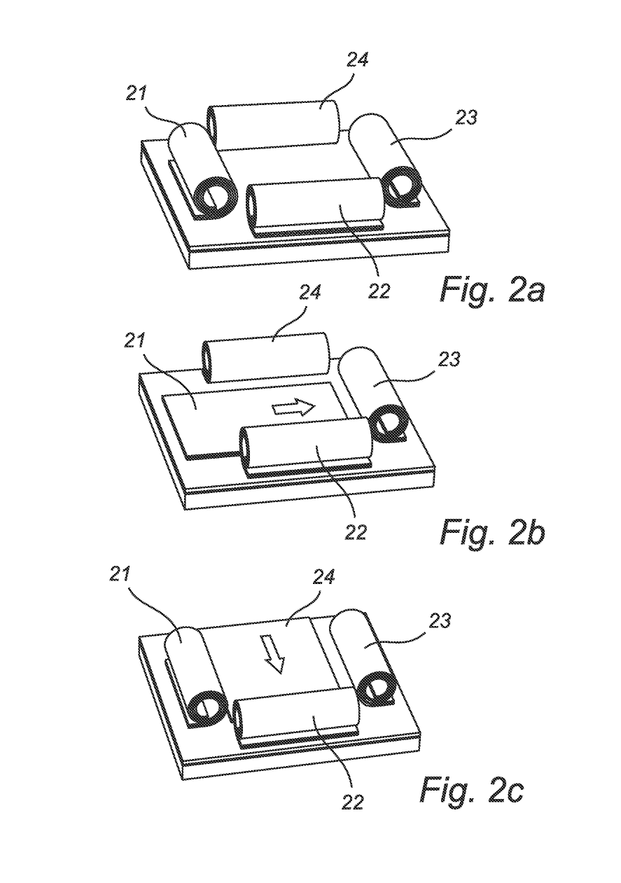

FIGS. 2a-c show various configurations of a light influencing element, wherein the second electrode layer comprises several portions, here in form of four differently structured in plane rollable electrodes 21, 22, 23, 24. Here, the electrodes are arranged to form a square along the edges of the light influencing element in their rolled-up state, wherein the four electrodes are arranged on one of the four edges of the light influencing element each. Each rollable electrode unrolls from its edge of the light influencing element, and since each of the four portions of this embodiment forms as big a square as the square formed light influencing element when being unrolled, each electrode covers the light influencing element completely. Further, the different electrodes are unrolled at different times by applying a sufficient voltage difference between the first electrode layer and the desired electrode. In FIG. 2a there is no voltage applied, and hence, no electrode is unrolled. In FIG. 2b, electrode 21 is unrolled to influence the light in one way, and in FIG. 2c, electrode 24 is unrolled to influence the light in another way.

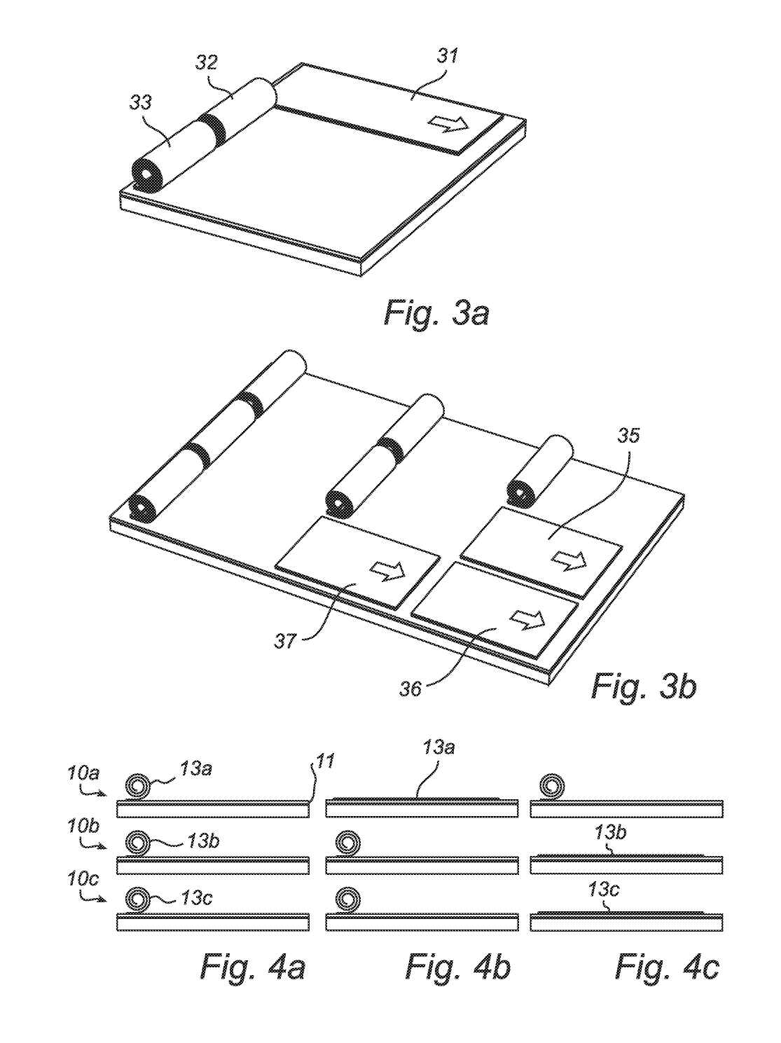

FIG. 3a-b show two other configurations. In FIG. 3a, an example where the second electrode layer comprises several portions, here in form of three in-plane rollable electrodes, is illustrated, whereas nine in-plane rollable electrodes are present in the example of FIG. 3b. In FIG. 3a electrode 31 is unrolled, while electrode 32 and electrode 33 are rolled up. In FIG. 3b three electrodes 35-37, of nine electrodes are unrolled while the remaining electrodes stay in the rolled up state. In these embodiments, each electrode covers a square formed part of the area of the light influencing element when the electrode is unrolled, and none of the electrodes are overlapping another electrode if being unrolled at the same time. Hence, if all three rollable electrodes in FIG. 3a or all nine rollable electrodes in FIG. 3b are unrolled simultaneously, they cover the entire light influencing element in common. A voltage difference is applied between the first electrode layer and the unrolled second electrodes to unroll them and keep them in the unrolled state.

In FIG. 4a-c parts equivalent of those in FIG. 1 are denoted by the same numerals. In FIG. 4a-c three light influencing elements 10a, 10b, 10c of FIG. 1 are arranged in a stacked structure. Here, the light influencing elements are equally sized and stacked on top of each other, resulting in that when more than one second electrode layer 13a-c is in the unrolled state, through applying a voltage difference between the first electrode layer 11 and the stacked second electrode layers 13a-c, they form a combined influence on the light emitted from a LED (not shown in FIG. 4). In FIG. 4a all three light influencing elements 13a-c are in the rolled-up state. In FIG. 4b one of the three light influencing element 13a is in the unrolled state influencing the light from the LED. In FIG. 4c, however, two light influencing elements 13b-c are in the unrolled state forming a combined influence on the light.

It should be noted that the variations illustrated in FIGS. 2-4 represent examples only and that many other variations are apparent to a person skilled in the relevant art.

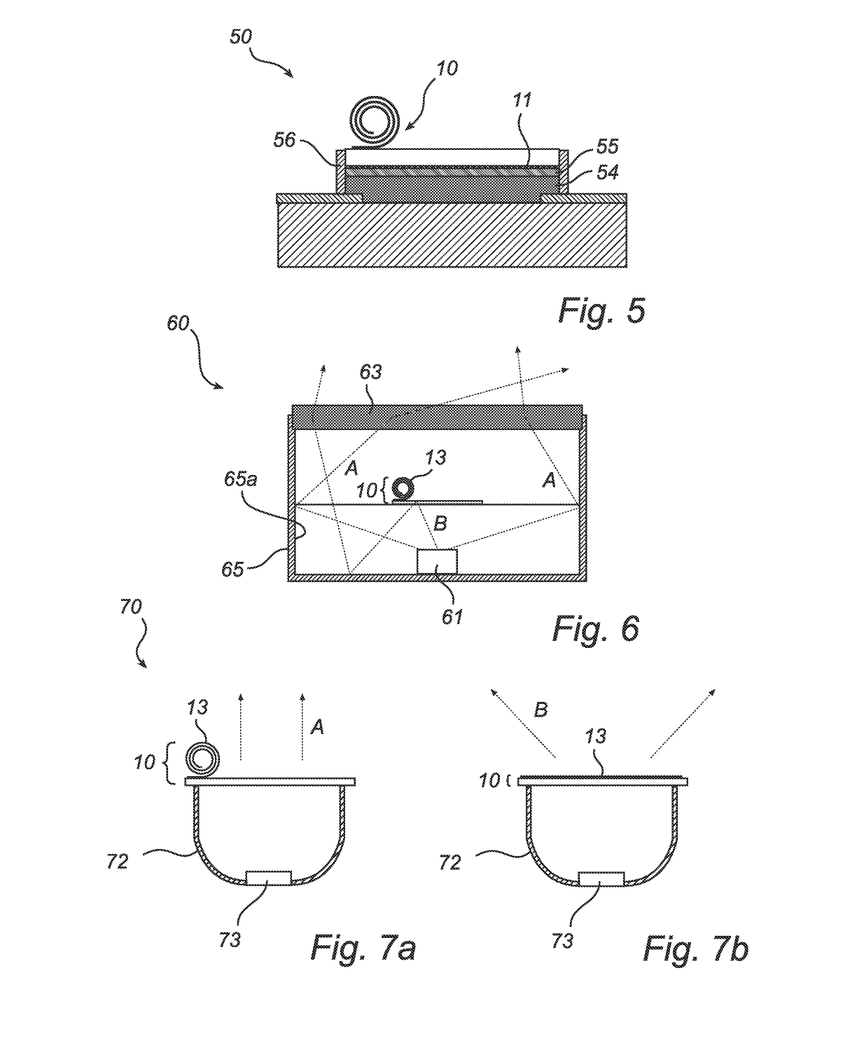

FIG. 5 illustrates a lighting device 50. In FIG. 5 parts equivalent of those in FIG. 1 are denoted by the same numerals. The light influencing element 10 is mounted on a LED chip 54. There is an optical contact layer 55 between the LED chip 54 and the first electrode layer 11. There is also a reflector 56 surrounding the lighting device, to collimate the light. The light influencing element 10 may act as a color and color temperature converter, by containing a luminescent phosphor material. For example, the light influencing element 10 may produce white light by using one or more various luminescent phosphor materials comprised in e.g. the second electrode layer 13 to, in its unrolled state, convert the emitted blue light from the LED into light of a longer wavelength.

If the reflector 56 is not present the device could act as a side-top emitter, the second electrode layer 13 being the side emitter, which directs the majority of the light sidewards from the LED.

FIG. 6 illustrates a lighting device 60. In FIG. 6 parts equivalent of those in FIG. 1 are denoted by the same numerals. The lighting device 60 in FIG. 6 is arranged inside a chamber 65 which inside 65a is a diffuse reflector. The chamber 65 has an exit opening, where a diffuser 63 is mounted, and a LED 61 is mounted in the bottom of the chamber 65. A light influencing element 10, as described in FIG. 1, is arranged between, and on a distance from, the LED 61 and the diffuser 63 in the middle of the chamber 65. The LED 61 emits light beams A and B, and when the second electrode layer 13 of the light influencing element 10 is unrolled the light beams B emitted from the LED 61 pass through the light influencing element 10 to be converted to another color. The light beams A does not pass through the light influencing element and are instead diffusely reflected and mixed with the converted light. In other words, the non-influenced light beams A and the influenced light beams B are mixed in the mixing chamber, formed by the chamber 65.

FIG. 7 illustrates a lighting device 70. In FIG. 7 parts equivalent of those in FIG. 1 are denoted by the same numerals. The beam shaping lighting device 70 in FIG. 7a-b comprises a LED 73, a light influencing element 10, and a collimator 72, which is based on total internal reflection. The LED 73 is arranged in the bottom of the collimator 72, and the light influencing element 10 is arranged at the exit opening of the collimator 72, opposite the LED 73. LED 73 emits light beams A and B. When the second electrode layer 13 of the light influencing element 10 is in the rolled-up state the light beams A are not influenced by it, as shown in FIG. 7a. The light beams A are instead only reflected by the collimator 72. When the second electrode layer 13 of the light influencing element 10 is in the unrolled state however, the light beams B are influenced by it, as shown in FIG. 7b, adjusting the shape direction and the collimation of the light. The adjustment may be achieved by providing the second electrode layer with e.g. a surface relief or a holographic phase structure providing refractive index variations. The collimator may be a total internal reflection element or an element based on a metallic or dielectric reflector.

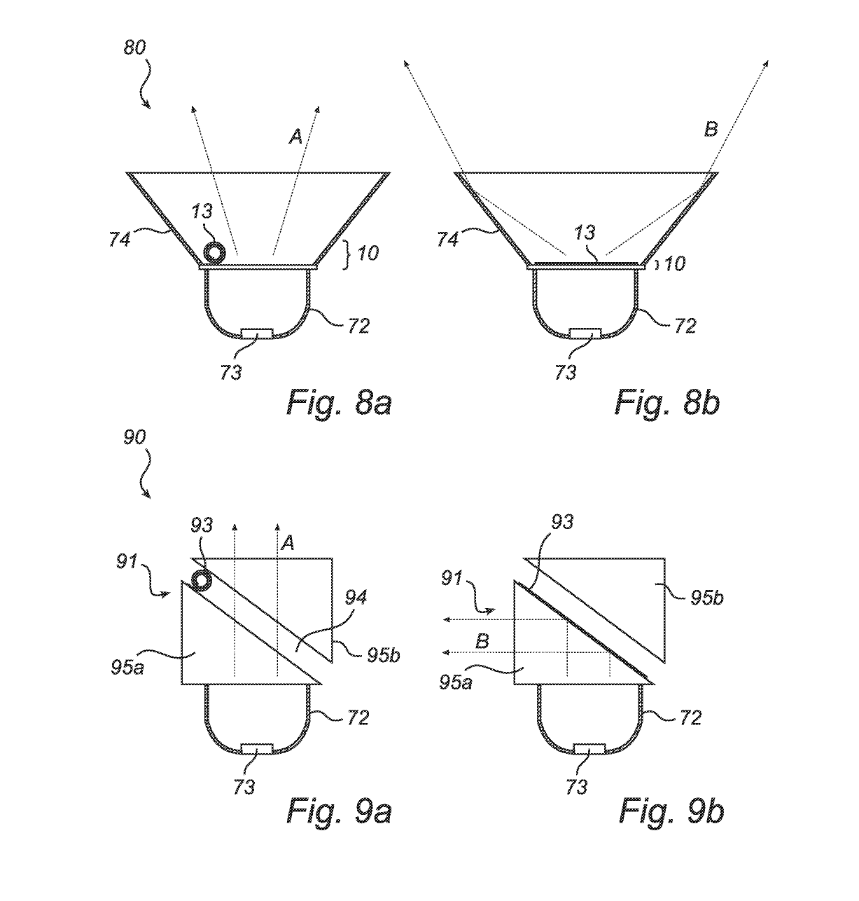

As illustrated in FIG. 8, the lighting device 70 may be provided with a second collimator 74, so as to form a two stage reflector configuration. When the second electrode layer 13 of the light influencing element 10 is rolled up the light beams A will not be influenced by the second collimator 74, as shown in FIG. 8a. The light beams A are instead just reflected by the first collimator 72.

When the second electrode layer 13 of the light influencing element 10 is unrolled the light beams B will be shaped by it, and directed to the second collimator 74, which shapes the beams of light B, as shown in FIG. 8b.

FIG. 9 illustrates a lighting device 90. In FIG. 9 parts equivalent of those in FIG. 7 are denoted by the same numerals. Here, a light influencing element 91 comprises a substrate 95a that is triangular to form an inclined surface for the rollable second electrode layer 93 to unroll on, which substrate is arranged above, and adjacent to, the exit opening of the collimator 72. The second electrode layer 93 is a reflector, and is arranged at the uppermost part on the inclined substrate in the rolled-up state. The LED 73 emits light beams A and B. When the rollable electrode 93 is rolled up, the light passes through the substrate 95a. When the electrode is unrolled along the inclined surface, the light beams will be reflected sideways.

It is moreover desirable to add a second optical element 95b above the substrate 95a. The second optical element 95b must be arranged on a distance from the substrate 95a so as to leave a spacing 94 for the second electrode layer in its rolled-up state and to unroll within. The optical element 95b is added in order to compensate for the different light path lengths through the substrate 95a, when the second electrode layer 93 is in the rolled-up state. Accordingly, the optical element 95b in this embodiment has the same triangular shape as the substrate 95a, and is arranged in a mirrored manner with respect to the substrate 95a.

In FIG. 9a the rollable second electrode layer 93 is in the rolled up state being arranged in the uppermost part of the inclined substrate 95a in the spacing 94 between substrate 95a and the optical element 95b. Since the other layers of the light influencing element 91 are transparent, they do not influence the light beams A emitted by the LED 73. The light emitted from the LED 73 is hence only influenced by the collimator 72.

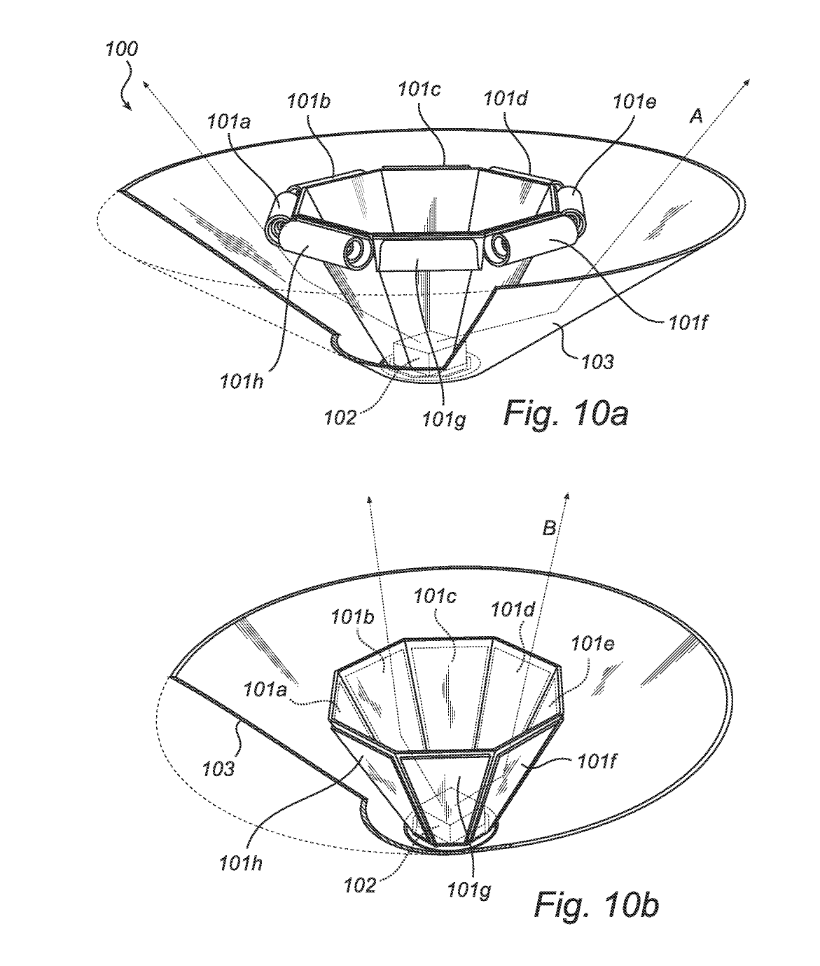

In FIG. 9b, however, the second electrode layer 93 of the light influencing element 91 is unrolled on its substrate 95a, to form an angular reflecting surface. The light emitted from the exit of the collimator 72 is thereby reflected by the light influencing element 91, altering the direction of the beams B. FIG. 10a-b illustrate a lighting device 100 that comprises a plurality of light influencing elements 101, similar to the light influencing element described in FIG. 1 except for that the second electrode is a reflector, and that all layers of the light influencing element 101 are wedge shaped. The wedge shaped light influencing elements 101a-h forms a funnel in common, that is arranged on the LED 73, and inside the outer reflector 103.

In the rolled-up state, as shown in FIG. 10a, the plurality of second electrodes of the light influencing elements 101a-h form an inner circle in the exit opening of an outer reflector 103, which circle circumference is smaller than the circumference of the exit opening circumference of the outer reflector 103. When the second electrode layers of the light influencing elements 101a-h are rolled-up the remaining layers, which are transparent, forms a transparent funnel on the LED 73, inside the outer reflector 103. The fact that the remaining layers of the light influencing elements 101a-h are transparent results in that the light beams A are not influenced by it. The beams of light A emitted from the LED 102 are instead reflected by the outer reflector 103, since each of the plurality of reflective second electrodes of the light influencing elements 101a-h are in the rolled-up state.

In FIG. 10b, however, each of the second electrode layers of the light influencing elements 101a-h are unrolled to cover the wedge shaped substrate of the light influencing elements 101a-h. To unroll and cover the transparent wedge shaped surface, each second electrode of the light influencing element 101 is wedge shaped too. In the unrolled state each light influencing element 101 hence form a wedge which is tapered towards the LED 102. As a result, the light influencing elements 101a-h form an inner funnel-shaped reflector in common, which funnel-shaped reflector is arranged inside the outer reflector 103. The actively formed inner reflector collimates the beams of light B. That is, the outer reflector 103 of FIG. 10a acts on the light when the light influencing elements 101a-h are rolled-up, whereas the inner reflector of FIG. 10b is formed when the light influencing elements 101a-h are unrolled, becoming the reflector that acts on the light.

In the embodiments described above the direction, shape, or collimation of light can be influenced when non light absorbing elements are used. Therefore the only losses might be due to reflection and high fraction (more than 80%) of the photons generated by the light source leave the device meaning an extremely high quantum efficiency. When the direction, shape, or collimation light is influencing element comprises a metallic reflector higher losses might occur.

In the embodiments described above when color and color temperature changes are induced there are some extra energy losses due to absorption and reemission. For example blue light emitted by a LED can be converted to red or green light when the blue light is completely absorbed and reemitted at red or green by phosphor layers. When it comes to white light, blue light is partially absorbed and converted to yellow light. The mixture of blue and yellow light has the characteristics of white light. In the conversion process of for example highly energetic blue light to red light with a high quantum efficiency (for example 100% quantum efficiency; meaning 100% of the blue photons are converted to red photons) there is still a loss of power, since the energy of red light is lower than blue light. If blue light with a wavelength of 450 nm is converted to red light with a wavelength of 620 nm there is an energy loss of 27.4%. If the intrinsic quantum efficiency of the phosphor material in the color converting element is 80% this loss increases to 100−(100−27.4)*0.8=42%. Adding the system losses, such as reflections, the overall quantum efficiency of the system will be further reduced, to e.g. 40%-60%. The total intensity loss during the conversion of blue light to red light can then be more than 50%. This is still much lower than losses that occur in e.g. a display device, where white light is emitted, and partially absorbed to generate various colors. In that case when for example red light needs be produced from white light 100% of green and 100% of blue light is completely absorbed and therefore lost.

The person skilled in the art realizes that the present invention is not limited to the preferred embodiments. For example, a lighting device may include several combinations of influence on the beam of light, e.g. combinations of converting the color and shape of the light simultaneously; or the portions of a second electrode layer may form non-square formations across the path of light emitted from a LED.

1. A high quantum efficiency lighting device comprising
a solid state light source,
at least one light influencing element, arranged in an optical path of the light emitted from the solid state light source, which light influencing element comprises
a first electrode layer, and
a second electrode layer,
wherein the second electrode layer is biased to remain in a rolled-up state, and adapted to be unrolled into an unrolled state in response to an electric potential applied between the first and second electrode layers, said second electrode layer in its unrolled state, extending across said optical light path, and being adapted to influence light emitted from the solid state light source.

2. The high quantum efficiency lighting device according to claim 1 wherein the quantum efficiency of the light influencing element is at least 40%.

3. The high quantum efficiency lighting device according to claim 1 wherein the second electrode layer comprises a dielectric layer.

4. The high quantum efficiency lighting device according to claim 3 wherein the dielectric layer comprises phosphors, luminescent material, adapted to convert light to another color.

5. The high quantum efficiency lighting device according to claim 3 wherein the dielectric layer comprises a light direction altering surface relief or has a light direction altering internal structure.

6. The high quantum efficiency lighting device according to claim 1 wherein said second electrode layer is adapted to act as a reflector.

7. The high quantum efficiency lighting device according to claim 1 wherein said second electrode layer comprises at least two separately rollable portions arranged to extend across the same part of the path of light emitted from the solid state light source.

8. The high quantum efficiency lighting device according to claim 1 wherein said second electrode layer comprises at least two separately rollable portions arranged to extend across different parts of the path of light emitted from the solid state light source.

9. The high quantum efficiency lighting device according to claim 1 comprising at least two light influencing elements arranged in a stacked structure.

10. The high quantum efficiency lighting device according to claim 1 wherein the light influencing element is arranged in optical contact with the solid state light source.

11. The high quantum efficiency lighting device according to claim 1 further comprising
a chamber, of which the inside is a diffuse reflector, and
a diffuser, arranged at the exit opening of said chamber,
wherein the light influencing element is arranged between the solid state light source and said diffuser, at a distance from the solid state light source, which light influencing element is adapted to influence a part of the light emitted from the solid state light source, which part corresponds to the part of the path of light covered by the extension of the second electrode layer in its unrolled state, allowing remaining light to remain non-influenced, passing the light influencing element directly to said diffuser, the non-influenced light being mixed with the influenced light in said chamber.

12. The high quantum efficiency lighting device according to claim 1, further comprising
a first collimator, arranged between the solid state light source and the light influencing element,
wherein the light influencing element is arranged to cover an exit opening of said first collimator, and which light influencing element is arranged to adjust shape, direction and collimation of a beam of light emitted from the solid state light source, when the second electrode is in its unrolled state.

13. The high quantum efficiency lighting device according to claim 12, further comprising
a second collimator, arranged to collimate light that have passed through and been influenced by the second electrode layer being in its unrolled state.

14. The high quantum efficiency lighting device according to claim 6, comprising a plurality of tapered light influencing elements arranged to form a funnel shaped reflector when said plurality of second electrode layers are in the unrolled state, said funnel shaped reflector being arranged with its narrow opening on the emitting side of the solid state light source.

15. The high quantum efficiency lighting device according to claim 14, further comprising an outer reflector, adapted to reflect the light when the plurality of second electrode layers of the light influencing elements are in a rolled-up state.
